(19) United States
(12) Patent Application Publication
(10) Pub. No.: US 2008/0153041 A1
(43) Pub. Date: Jun. 26, 2008

(54) Exposure Method and Apparatus

(75) Inventor: Yoshiharu Sasaki, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 11/666,620

(22) PCT Filed: Oct. 27, 2005
(86) PCT No.: PCT/JP05/20161

§ 371 Date: Apr. 30, 2007

(30) Foreign Application Priority Data
Oct. 28, 2004 (JP) 2004-314047

(51) Int. Cl. G03F 7/20; G03B 27/42

(52) U.S. Cl. 430/322; 355/53

(57) ABSTRACT

When exposing a pattern on a recording medium, such as a printed wiring board on which a photosensitive layer having sensitivity to light, such as a resist layer or the like, is stacked, the photosensitive layer is prevented from unduly becoming irremovable or liable to be peeled off, while maintaining the adhesion of the layer. In order to achieve this, when a wiring pattern is exposed on a resist layer formed on a substrate by an exposure apparatus 3, irradiation energy of the exposure light is controlled to become greater in an edge portion of the wiring pattern than in the other portion of the wiring pattern.

### TECHNICAL FIELD

The present invention relates to an exposure method and apparatus for exposing a predetermined pattern, such as a wiring pattern of a printed wiring board, on a photosensitive layer stacked on a recording medium, such as a printed wiring board, by a light beam emitted from a laser source or the like.

### BACKGROUND ART

Various types of exposure systems for performing image exposure by a light beam, modulated according to image data using a spatial modulation device, such as a digital micro-mirror device (DMD) or the like, are proposed. As one of the applications of such exposure systems, application to the manufacturing process for printed wiring boards is known as described, for example, in Japanese Unexamined Patent Publication No. 2004-001244.

Generally, a printed wiring board is manufactured through the following processes. First, a dry film resist layer (hereinafter, simply referred to as “resist layer”), made of a photosensitive material that solidifies by receiving light, is formed on a conductive layer (e.g., copper film) provided on a substrate for forming a wiring pattern. Then, the resist layer is exposed by a light beam in a shape identical to the wiring pattern. Thereafter, through development of the resist layer, a portion of the resist layer not exposed by the light beam is removed to form a pattern identical to the wiring pattern (resist pattern), and the conductive layer is etched using the resist pattern as the mask. Then, the wiring pattern is formed on the conductive layer by removing the resist layer.

Further, a solder resist, which solidifies by receiving light, is applied to the conductive layer and semi-solidified, which is then exposed by the light beam in a shape identical to a pattern representing an electrode region which is open with the periphery portion on the upper face coated by a predetermined width. Then the solder resist is developed to remove a portion thereof not exposed by the light beam and the solder resist is fully solidified. Thereafter, a nickel-gold plated layer is formed in order to improve solder wettability, and thereby a printed wiring board is completed.

Conventionally, the exposure of the resist layer and solder resist layer described above are performed using mask films, having openings of the wiring pattern and the pattern representing an electrode region which is open with the periphery portion on the upper face coated by a predetermined width respectively, which are brought into close contact with the resist layer and solder resist layer respectively. But, the use of an image recording system described in Japanese Unexamined Patent Publication No. 2004-001244 allows a pattern to be recorded (exposed) on a resist layer and a solder resist layer directly.

As describe above, when exposing a wiring pattern and the like, low adhesion of the resist layer and solder resist layer (photosensitive layers) causes various problems. For example, if the adhesion of the resist layer is low, an edge portion of the resist layer may be separated from the substrate, and developing solution may intrude between the resist layer and the substrate during the development process, which prevents proper etching and plating to be performed in the subsequent etching and plating processes. In the solder resist forming process, the printed wiring board is exposed to a pretreatment solution and a plating solution after development. If the adhesion of the solder resist layer is low, an edge portion of the solder resist layer may be separated from the substrate, and proper plating is prevented.

Therefore, when performing exposure of a wiring pattern and the like, it is necessary to increase the irradiation energy of the light beam to a certain degree to prevent the separation of the exposed portion of the resist layer and solder resist layer.

Excessive irradiation energy, however, may prevent the resist layer to be removed completely after etching. Further, in the case of solder resist layer, excessive irradiation energy may result in a large amount of solidification contraction due to excessive photopolymerization reaction, so that the entire solder resist layer may become liable to be peeled off in the process for solidifying the solder resist layer.

### DISCLOSURE OF INVENTION

The present invention has been developed in view of the circumstances described above, and it is an object of the present invention to enabling a pattern exposure to be performed without causing the photoconductive layer to become irremovable or liable to be separated while maintaining adhesion of the photosensitive layer.

An exposure method of the present invention is an exposure method for exposing a predetermined pattern on a photosensitive layer, which is stacked on a recording medium and has sensitivity to light emitted from a predetermined light source, with the light having predetermined irradiation energy. Here, the predetermined pattern is exposed on the photosensitive layer with greater irradiation energy in an edge portion of the predetermined pattern than in the other portion thereof.

As for materials of the photosensitive layer, photosensitive materials having sensitivity to light and solidify by receiving light, such as a dry film resist (DFR), a solder resist, and the like, may be used.

As for the predetermined light source, for example, a light source that emits ultraviolet light or the like to which the photosensitive layer is sensitive may be used. As for the light source, any type of light source may be used as long as it is capable of exposing the recording medium, such as a laser source that emits a light beam, a light source for performing a whole surface exposure, or the like.

Preferably, the irradiation energy in the edge portion is 1.1 to 3.0 times the irradiation energy in the other portion.

Preferably, the edge portion is a portion of the predetermined pattern inside of the edge within 100 μm from the edge.

Preferably, the edge portion is a portion of the predetermined pattern inside of the edge within 20 μm from the edge.

Preferably, the edge portion is less than or equal to ⅓ of a minimum width of the predetermined pattern.

In the exposure method of the present invention, the predetermined light source may be a light source that emits a light beam, and the predetermined pattern may be exposed on the photosensitive layer by scanning the recording medium with the light beam, while controlling the irradiation energy of the light beam so as to become OFF in a region of the recording medium other than the predetermined pattern, and to become greater in the edge portion of the predetermined pattern than in the other portion thereof.

Further, in the exposure method of the present invention, the predetermined light source may be a light source that emits a light beam, and the predetermined pattern may be exposed on the photosensitive layer by scanning the recording medium with the light beam such that the light beam becomes OFF in a region of the recording medium other than the predetermined pattern, and becomes ON in the region of the predetermined pattern, and, after the scanning, scanning the recording medium with the light beam such that the light beam becomes ON only in the edge portion of the predetermined pattern.

Still further, in the exposure method of the present invention, the predetermined light source may be a light source that emits a light beam, and the predetermined pattern may be exposed on the photosensitive layer by scanning the recording medium with the light beam such that the light beam becomes OFF in a region of the recording medium other than the predetermined pattern, and becomes ON in the region of the predetermined pattern, and, after the scanning, scanning the recording medium with the light beam, while controlling the irradiation energy of the light beam so as to become OFF in the region of the recording medium other than the predetermined pattern, and to become greater in the edge portion of the predetermined pattern than in the other portion thereof.

Further, in the exposure method of the present invention, the predetermined pattern may be exposed on the photosensitive layer by irradiating the light on the recording medium through a mask film, which optically masks a region of the recording medium other than the predetermined pattern, and has a greater transmittance in the region thereof corresponding to the edge portion of the predetermined pattern than in the region thereof corresponding to the other portion of the predetermined pattern.

Still further, in the exposure method of the present invention, the predetermined pattern may be exposed on the photosensitive layer by irradiating the light on the recording medium through a first mask film, which optically masks a region of the recording medium other than the predetermined pattern and transmits light in the region thereof corresponding to the predetermined pattern, and through a second mask film, which transmits light only in the region thereof corresponding to the edge portion of the predetermined pattern, or has a greater transmittance in the region thereof corresponding to the edge portion of the predetermined pattern than in the region thereof corresponding to the other portion of the predetermined pattern respectively.

An exposure apparatus of the present invention is an apparatus for exposing a predetermined pattern on a photosensitive layer, which is stacked on a recording medium and has sensitivity to light emitted from a predetermined light source, with the light having predetermined irradiation energy. The apparatus includes an exposure control means for exposing the predetermined pattern on the photosensitive layer with greater irradiation energy in an edge portion of the predetermined pattern than in the other portion thereof.

In the exposure apparatus of the present invention, the predetermined may be a light source that emits a light beam; the apparatus may further include a scanning means for modulating and scanning the light beam according to the predetermined pattern; and the exposure control means maybe a means for controlling the scanning means such that the predetermined pattern is exposed on the photosensitive layer by scanning the recording medium with the light beam, while controlling the irradiation energy of the light beam so as to become OFF in a region of the recording medium other than the predetermined pattern, and to become greater in the edge portion of the predetermined pattern than in the other portion thereof.

Further, in the exposure apparatus of the present invention, the predetermined may be a light source that emits a light beam; the apparatus may further include a scanning means for modulating and scanning the light beam according to the predetermined pattern; and the exposure control means may be a means for controlling the scanning means such that the predetermined pattern is exposed on the photosensitive layer by scanning the recording medium with the light beam such that the light beam becomes OFF in a region of the recording medium other than the predetermined pattern, and becomes ON in the region of the predetermined pattern, and, after the scanning, scanning the recording medium with the light beam such that the light beam becomes ON only in the edge portion of the predetermined pattern.

Still further, in the exposure apparatus of the present invention, the predetermined may be a light source that emits a light beam; the apparatus may further include a scanning means for modulating and scanning the light beam according to the predetermined pattern; and the exposure control means may be a means controlling the scanning means such that the predetermined pattern is exposed on the photosensitive layer by scanning the recording medium with the light beam such that the light beam becomes OFF in a region of the recording medium other than the predetermined pattern, and becomes ON in the region of the predetermined pattern, and, after the scanning, scanning the recording medium with the light beam, while controlling the irradiation energy of the light beam so as to become OFF in the region of the recording medium other than the predetermined pattern, and to become greater in the edge portion of the predetermined pattern than in the other portion thereof.

Further, in the exposure apparatus of the present invention, the exposure control means may be a means for exposing the predetermined pattern on the photosensitive layer by irradiating the light on the recording medium through a mask film, which optically masks a region of the recording medium other than the predetermined pattern and has a greater transmittance in the region thereof corresponding to the edge portion of the predetermined pattern than in the region thereof corresponding to the other portion of the predetermined pattern.

Still further, in the exposure apparatus of the present invention, the exposure control means may be a means for exposing the predetermined pattern on the photosensitive layer by irradiating the light on the recording medium through a first mask film, which optically masks a region of the recording medium other than the predetermined pattern and transmits light in the region thereof corresponding to the predetermined pattern, and through a second mask film, which transmits light only in the region thereof corresponding to the edge portion of the predetermined pattern, or has a greater transmittance in the region thereof corresponding to the edge portion of the predetermined pattern than in the region thereof corresponding to the other portion of the predetermined pattern respectively.

According to the present invention, a predetermined pattern is exposed on a recording medium with greater irradiation energy in an edge portion of the predetermined pattern than in the other portion thereof. Thus, the photosensitive layer is more solidified in the edge portion, so that the adhesion between the edge portion of the photosensitive layer and the recording medium is increased. This may prevent the separation of the edge portion of the predetermined pattern formed in the photosensitive layer in the subsequent processes after exposure.

Accordingly, if the recording medium on which the photosensitive layer is stacked is a substrate on which a resist layer for producing a printed wiring board, the developing solution is prevented from intruding between the resist layer and the substrate in the development process after exposure, which allows desired etching and plating to be performed satisfactorily in the subsequent etching and plating processes. Further, greater irradiation energy is applied only to the edge portion of the predetermined pattern, so that the resist layer may be removed completely after etching.

Further, if the recording medium on which the photosensitive layer is stacked is a substrate on which a solder resist layer for producing a printed wiring board, the pretreatment and plating solutions are prevented from intruding between the solder resist layer and the substrate in the plating process after development. As a result, desired plating may be performed satisfactorily. Further, greater irradiation energy is applied only to the edge portion of the predetermined pattern, so that the photopolymerization reaction does not become excessive, and the solidification contraction falls within a permissible range, which may eliminate the likelihood that the solder resist layer is peeled off.

### BRIEF DESCRIPTION OF DRAWINGS

FIG. 1 is a schematic block diagram of a printed wiring board manufacturing system that includes an exposure apparatus according to an embodiment of the present invention, illustrating the construction thereof.

FIG. 2 is a perspective view of an exposure apparatus according to an embodiment of the present invention, illustrating the appearance thereof.

FIG. 3 is a perspective view of a scanner used in the exposure apparatus shown in FIG. 2.

FIG. 4A is a plan view of a photosensitive material, illustrating exposed regions formed thereon.

FIG. 4B is a drawing illustrating an arrangement of exposing areas of exposure heads.

FIG. 5 is a perspective view of an exposure head in the exposure apparatus shown in FIG. 2.

FIG. 6 is a cross-sectional view of the exposure head shown in FIG. 5 in the sub-scanning direction along the optical axis, illustrating the construction thereof.

FIG. 7 is a partially enlarged view of a DMD.

FIGS. 8A and 8B illustrate operations of the DMD.

FIG. 9 illustrates a pattern exposed in the present embodiment.

FIG. 10A is a plan view illustrating a region included in the pattern exposed in the present embodiment.

FIG. 10B is a cross-sectional view taken along the line I-I in FIG. 10A after exposure of the substrate.

FIG. 11A illustrates a pixel pattern, each pixel having a value of 1.

FIG. 11B illustrates a pixel pattern in which a pixel having a value of 1 and a pixel having a value of 0 are arranged alternately.

FIG. 12 illustrates an example mask film used in the present embodiment.

FIG. 13A illustrates an example mask film used in a first exposure when exposure is performed two times.

FIG. 13B illustrates an example mask film used in a second exposure when exposure is performed two times.

### BEST MODE FOR CARRYING OUT THE INVENTION

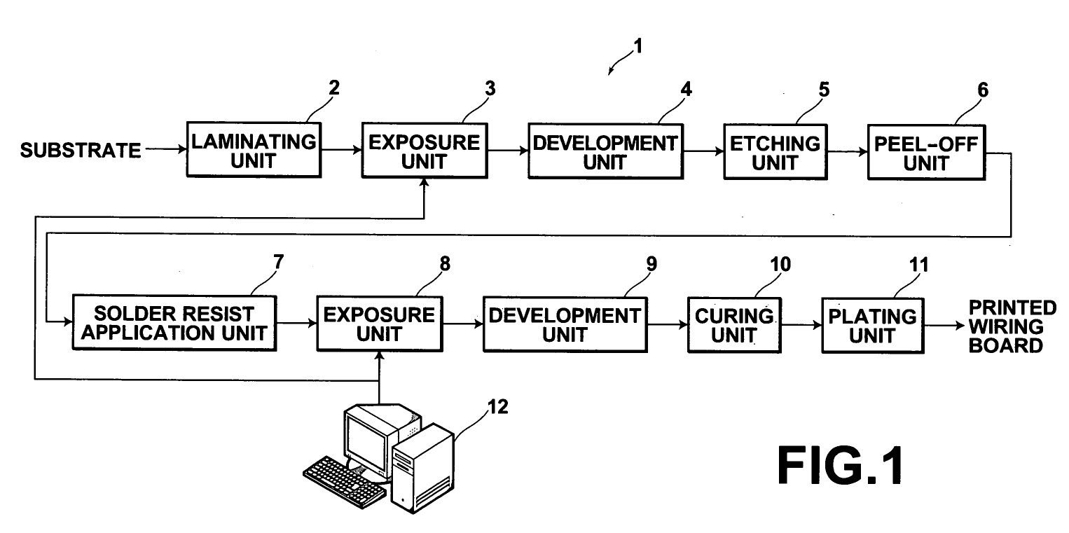

Hereinafter, exemplary embodiments of the present invention will be described with reference to the accompanying drawings. FIG. 1 is a schematic block diagram of a printed wiring board manufacturing system that includes an exposure apparatus according to an embodiment of the present invention, illustrating the construction thereof. As illustrated, the printed wiring board manufacturing system 1 includes: a laminating unit 2 for forming a resist layer on a copper foil formed on a substrate by laminating a dry film resist (DFR) thereon; an exposure apparatus 3 for exposing a wiring pattern on the resist layer; a development unit 4 for developing the exposed resist layer to form a resist pattern which is identical in shape to the wiring pattern; an etching unit 5 for etching the copper foil, formed on the substrate, on which the resist pattern is formed, to form the wiring pattern on the copper foil; and a peel-off unit 6 for peeling off the resist layer remaining on the substrate after etching. The manufacturing system 1 further includes: a solder resist application unit 7 for applying a solder resist on the substrate on which the wiring pattern is formed to form a solder resist layer thereon; an exposure apparatus 8 for exposing a pattern representing an electrode region which is open with the periphery portion on the upper face coated by a predetermined width (opening pattern) on the solder resist layer; a development unit 9 for developing the exposed solder resist layer to form a solder resist pattern which is identical in shape to the opening pattern; a curing unit 10 for solidifying the solder resist; a plating unit 11 for forming a nickel-gold plated layer in order to improve solder wettability of the electrode region; and a CAM (computer aided manufacturing) system (exposure control means) 12.

Note that the resist layer and solder resist layer are made of materials that solidify in an exposed region. Therefore, the wiring pattern is a pattern exposed in a place of actual wiring pattern, and the opening pattern is a pattern exposed in a place not opened.

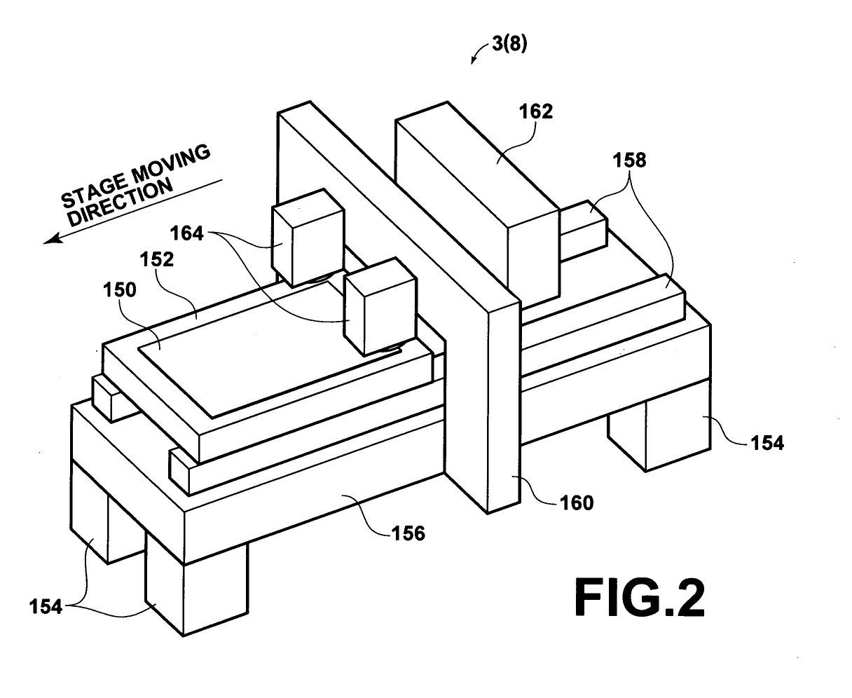

FIG. 2 is a perspective view of the exposure apparatus. The exposure apparatus 3 and exposure apparatus 8 have an identical structure, so that explanation of only the exposure apparatus 3 will be provided herein below. As illustrated in FIG. 2, the exposure apparatus 3 includes a plate-like stage 152 for holding thereon a sheet-like substrate, on which a resist layer is formed, by suction. Two guides 158 extending along the moving direction of the stage are provided on the upper surface of a thick plate-like mounting platform 156 which is supported by four legs 154. The stage 152 is arranged such that its longitudinal direction is oriented to the moving direction of the stage, and movably supported by the guides 158 to allow back-and-forth movements. Note that the exposure apparatus 3 also includes a not shown drive unit for driving the stage 152 along the guides 158.

An inverse U-shaped gate 160 striding over the moving path of the stage 152 is provided at the central part of the mounting platform 156. Each of the ends of the inverse U-shaped gate 160 is fixedly attached to each of the sides of the mounting platform 156. A scanner 162 is provided on one side of the gate 160, and a plurality of detection sensors 164 (e.g. two) for detecting the front and rear edges of the photosensitive material 150 is provided on the other side. The scanner 162 and detection sensors 164 are fixedly attached to the gate 160 over the moving path of the stage 152. The scanner 162 and detection sensors 164 are connected to a not shown controller that controls them.

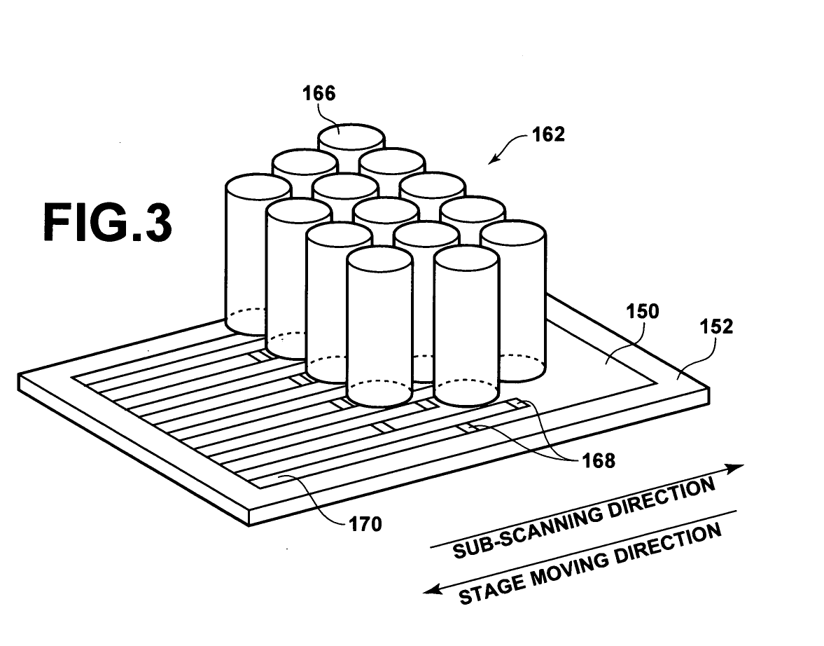

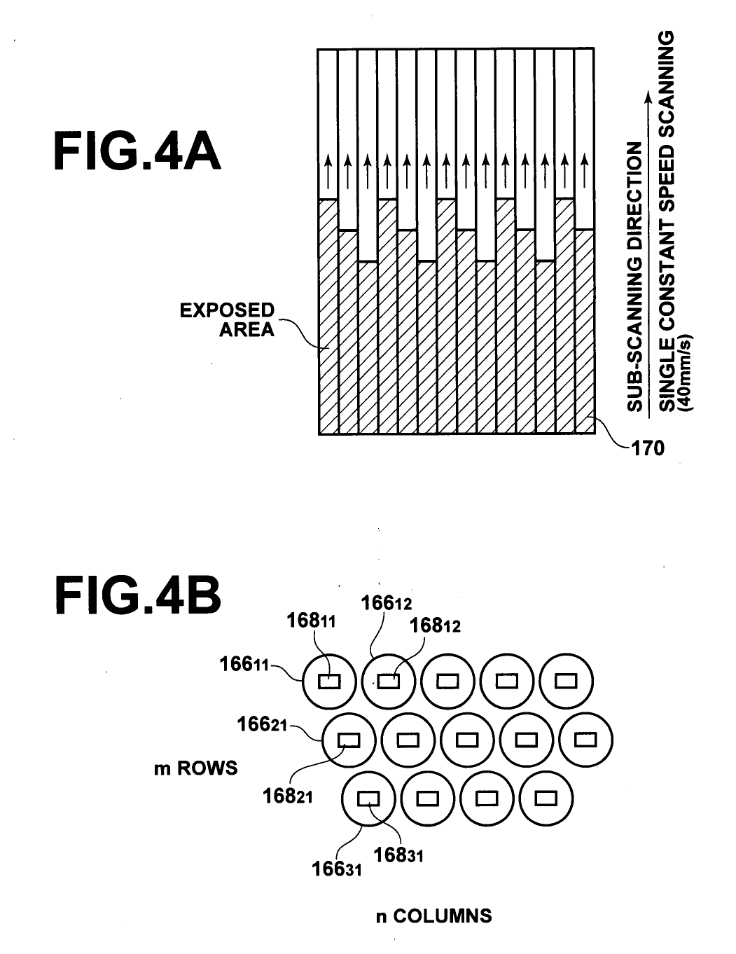

As shown in FIGS. 3 and 4B, the scanner 162 has a plurality of exposure heads 166 (e.g., 14) disposed in substantially a matrix form of “m” rows with “n” columns. In this example, four exposure heads 166 are disposed in the third row in relation to the width of the photosensitive material 150. Hereinafter, the exposure head disposed at the n^{th} column of the m^{th} row will be designated as exposure head 166.

The exposure area of an exposure head 166 has a rectangular shape with a short side oriented in the sub-scanning direction. Accordingly, a stripe-shaped exposed area 170 is formed on the photosensitive material 150 by each of the exposure heads 166 as the stage 150 is moved. Hereinafter, the exposure area of the exposure head disposed at the n^{th} column of the m^{th} row will be designated as the exposure area 168.

As illustrated in FIGS. 4A and 4B, each of the exposure heads disposed in a line in each row is shifted in the arrangement direction at a predetermined distance (product of the long side of the exposure area multiplied by a natural number, which is 2 in the present embodiment), so that the stripe-like exposed areas 170 are formed side by side without any gap between them in the direction orthogonal to the sub-scanning direction. Thus, the unexposed area between the exposure area 168₁₁ and 168₁₂ in the first row may be exposed by the exposure area 168₂₁ in the second row and the exposure area 168₃₁ in the third row.

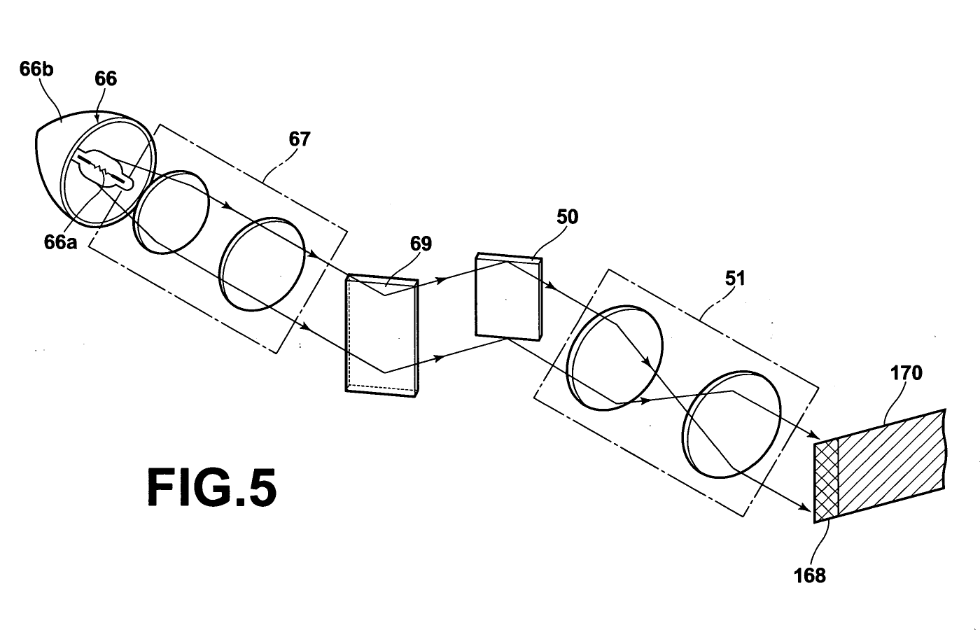

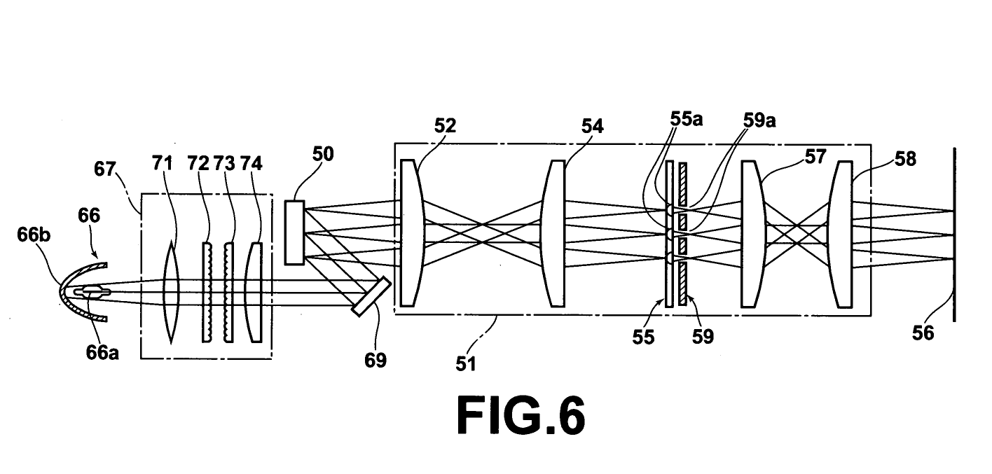

As illustrated in FIGS. 5 and 6, each of the exposure heads 166₁₁ to 166ₘₙ includes a digital micro-mirror device (DMD) 50, as a spatial optical modulation device for modulating an inputted light beam for each pixel according to pattern data received from CAM system 12. The DMD 50 is connected to a not shown controller which includes a data processing unit and a mirror drive control unit. The data processing unit generates a control signal for drive controlling each micro-mirror within a region of the DMD 50 to be controlled, with respect to each exposure head 166, based on inputted pattern data. Description of the region of the DMD 50 to be controlled will be provided later. Based on the control signal generated by the data processing unit, the mirror control unit controls the reflection surface angle of each micro-mirror of DMD 50, with respect to each exposure head 166. The description of how to control the reflection surface angle will be provided later.

A mercury lamp 66, a lens system 67 for focusing light emitted from the mercury lamp 66 on the DMD 50, after correcting light intensity distribution thereof, and a mirror 69 for reflecting the light transmitted through the lens system 67 toward the DMD 50 are disposed in this order on the light input side of the DMD 50. Note that the lens system 67 is depicted schematically in FIG. 5.

As illustrated in FIG. 6, the lens system 67 includes; a collimator lens 71 for collimating light emitted from a filament 66a of the mercury lamp 66 and collected on the front side by a reflector 66b; a micro-fly-eye lens 72 disposed in the optical path of the light transmitted through the collimator lens 71; another micro-fly-eye lens 73 disposed in opposite to the micro-fly-eye lens 72, and a field lens 74 disposed on the front side of the micro-fly-eye lens 73, i.e., on the side toward the mirror 69. Each of the micro-fly-eye lenses 72 and 73 includes multitudes of microscopic lens cells disposed vertically and horizontally. The light transmitted through each of the microscopic lens cells is inputted to the DMD 50 by overlapping with each other, so that the light intensity distribution of the light irradiated on the DMD 50 is equalized. In the mean time, a lens system 51 for focusing light, reflected by the DMD 50, on the scanning surface (exposure surface) of the photosensitive material 150 is disposed on the light reflection side of the DMD 50. The lens system 51 is disposed such that the DMD 50 and exposure surface are in conjugated relationship. The lens system 51 is depicted schematically in FIG. 5, but as illustrated in detail in FIG. 6, it includes: a magnifying imaging optical system of two lenses 52, 54; an imaging optical system of lenses 57, 58; a micro-lens array 55; and an aperture array 59, the micro-lens array 55 and an aperture array 59 being disposed between the two imaging optical systems. The micro-lens array 55 includes multitudes of micro-lenses, each corresponding to each pixel of the DMD 50. The aperture array 59 includes multitudes of apertures 59a, each corresponding to each micro-lens 55a.

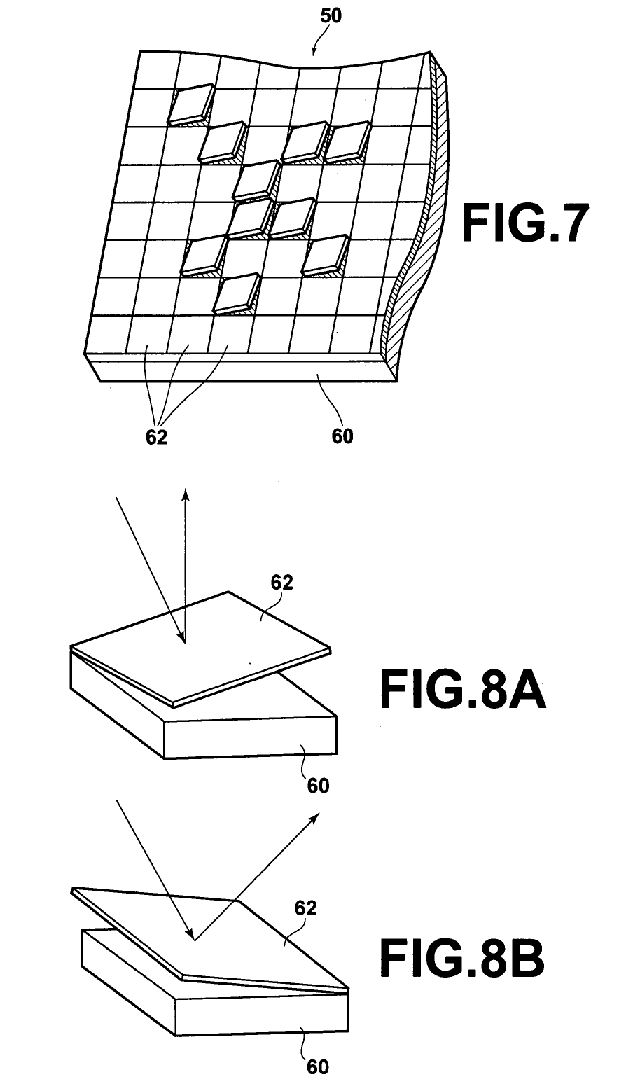

The DMD 50 includes tiny mirrors (micro-mirrors) 62 supported by support posts on SRAM cells (memory cells) 60 as shown in FIG. 7. It is a mirror device in which multitudes of tiny mirrors, constituting pixels, are arranged in a lattice pattern (e.g., 600×800). Each pixel has a micro-mirror 62 at the top supported by the support post, and a material having a high reflectance, such as aluminum or the like, is vapor deposited on the surface of the micro-mirror 62. The reflectance of the micro-mirror 62 is greater than or equal to 90%. A silicon-gate CMOS SRAM cell 60, which may be produced on a common manufacturing line for manufacturing semiconductor memories, is provided beneath each of the micro-mirrors 62 through the support post including a hinge and a yoke. The entire DMD is constructed monolithically.

When a digital signal is written into the SRAM cell 60 of the DMD 50, the micro-mirror supported by the support post is inclined within the range of ±α degrees (e.g., ±10 degrees) centered on the diagonal line relative to the substrate on which the DMD 50 is mounted. FIG. 8A illustrates the micro-mirror 62 inclined by +α degrees, which means that it is in on-state, and FIG. 8B illustrates the micro-mirror 62 inclined by −α degrees, which means that it is in off-state. Accordingly, by controlling the inclination of the micro-mirror 62 in each pixel of the DMD 50 according to image signals, in the manner as illustrated in FIG. 7, the light inputted to the DMD 50 is reflected to the inclination direction of each micro-mirror 62.

FIG. 6 is a partially enlarged view of the DMD 50, illustrating an example state in which some of the micro-mirrors of the DMD 50 are controlled to incline by + or −α degrees. The on-off control of each of the miro-mirrors 62 is performed by a not shown controller connected to the DMD 50. A light absorption material (not shown) is disposed in the direction to which light beams are reflected by off-state micro-mirrors 62.

Here, in the present embodiment, irradiation of the light beams is controlled so as to become greater in the edge portion of a pattern than in the portion other than the edge portion. The control method will be described in detail hereinafter.

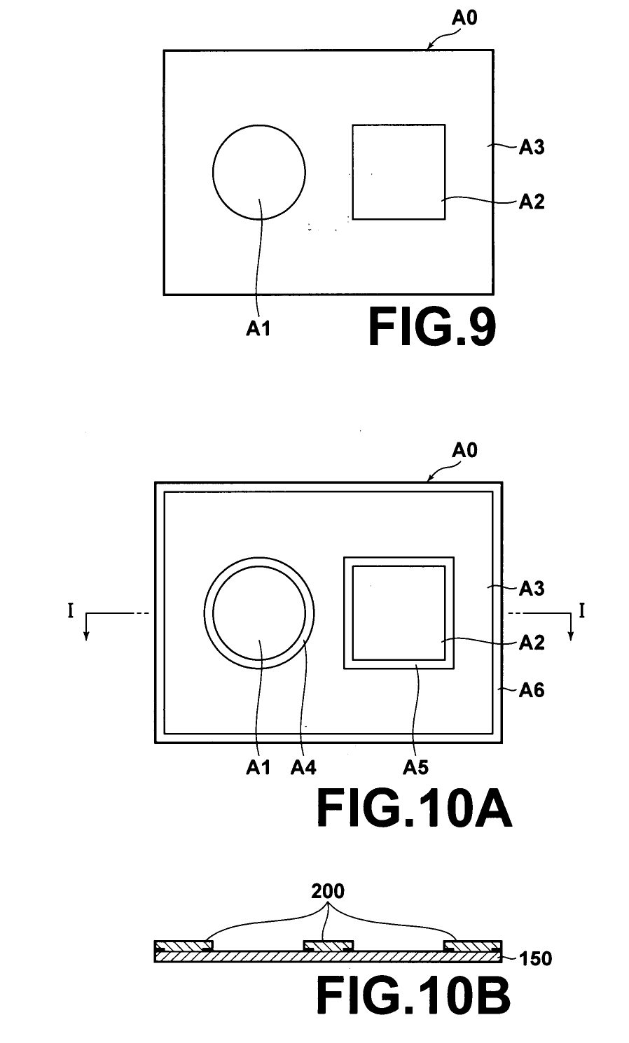

In the present embodiment, description will be made of a case in which a pattern to be exposed has a circular region A1, a square region A2, and a region A3, which is a region other than the region A1 and A2, within a horizontally long rectangular region A0, as illustrated in FIG. 9, and the light beam is irradiated only on the region A3. It will be appreciated, however, that the present embodiment is not limited to the exposure of the pattern illustrated in FIG. 9.

Pattern data outputted from the CAM system 12 are binary data, in which pixels of a region where light beam is irradiated have a value of 1, and pixels of other region than that have a value of 0. When a pattern is exposed, in order to control the irradiation of the light beam such that the irradiation energy becomes greater in an edge portion of the pattern than in the portion other than the edge portion, the CAM system 12 replaces certain pixel data selected from pixel data within the portion other than the edge portion of the pixel data constituting the pattern data to the value that turns off the light beam. More specifically, the distance between light beam irradiation positions in the other portion is set to ½ of the distance in edge portion to replace the value of pixel data with 0 for every other pixel.

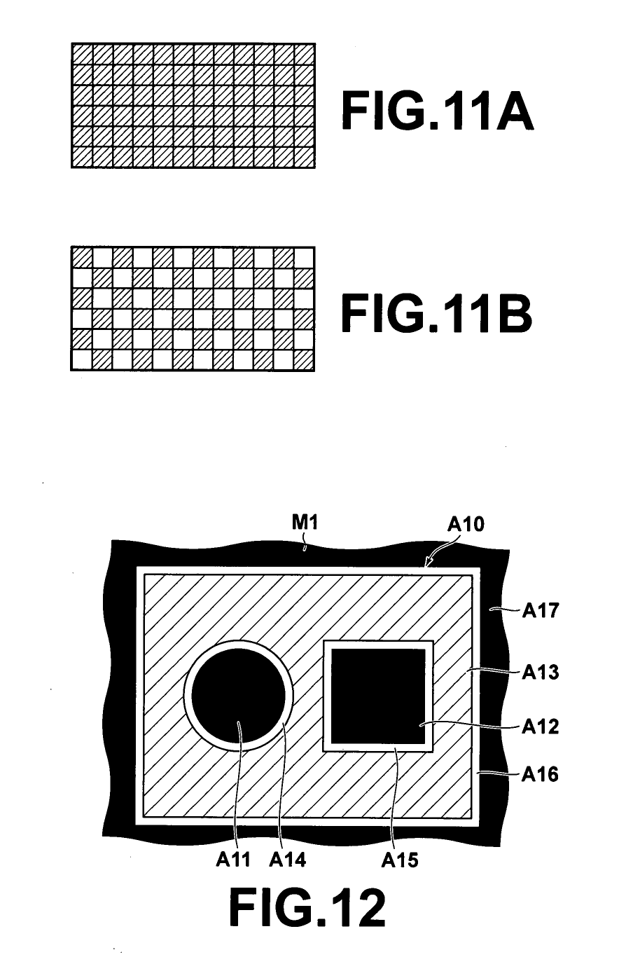

That is, as illustrated in FIG. 10A, the distance between light beam irradiation positions in the edge portion A4 of the circular region A1 within the region A3, edge portion AS of the square region A2 within the region A3, and edge portion A6 of the region A3 is doubled to that of the portion other than the portions A4, A5, and A6 within the region A3 (A3′). This causes the pattern data corresponding to the portions A4, A5, and A6 to have a value of “1” (hatched lines) in every pixel as illustrated in FIG. 11A, and the pattern data corresponding to the portion A3′ become a pattern in which a pixel having a value of “1” and a pixel having a value of “0” are arranged alternately, as illustrated in FIG. 11B. Accordingly, the portions A4, A5, and A6 are exposed with the irradiation energy twice as great as that for the portion A3′.

By performing the exposure in the manner as described above, the adhesion between the substrate 150 and the edge portion of the resist layer 200 may be increased, as illustrated in FIG. 10B (portions illustrated in black).

Note that the irradiation energy of the light beam may be changed variously by changing the distance between the irradiation positions. In the present embodiment, it is preferable that the distance between the irradiation positions is changed such that the portions A4, A5, and A6 are exposed with the irradiation energy which is 1.1 to 3.0 times that for the portion A3′.

The width of the edge portions A4, A5, and A6 is less than or equal to 100 μm, preferably less than or equal to 20 μm. When a pattern is exposed in a line, it is preferable that the width of the edge portion is less than or equal to ⅓ of the line width. More specifically, if the line width is 60 μm, the width of the edge portion is preferable to be less than or equal to 20 μm.

Next, an operation of the exposure apparatus will be described. Here, an operation of the exposure apparatus 3 that exposes a wiring pattern on a resist layer will be described.

The light, emitted from the mercury lamp 66 illustrated in FIGS. 5 and 6, having a wavelength, for example, in the range from 360 to 420 nm range is irradiated on the DMD 50, after equalized in light intensity distribution through the lens system 67 as described above. Pattern data corresponding to the wiring pattern is inputted to a not shown controller connected to the DMD 50, and tentatively stored in a frame memory in the controller.

The stage 152, with the substrate 150 illustrated in FIG. 2 suctioned thereon, is moved along the guides 158 at a constant speed from the upper stream to the down stream of the gate 160. When the fore edge of the substrate 150 is detected by the sensors 164 attached to the gate 160, when the stage 152 passing under the gate 160, the pattern data stored in the frame memory are sequentially read out for a plurality of lines at a time, and a control signal is generated by the data processing unit with respect to each exposure head 166 based on the readout pattern data. Then each of the micro-mirrors of the DMD 50, with respect to each exposure head 166, is on-off controlled by the mirror drive control unit based on the generated control signal.

While the light from the mercury lamp 66 is irradiated on the DMD 50, the light beam reflected by an on-state micro-mirror of the DMD 50 is condensed by the lens system 51 and focused on an exposure surface 56 of the substrate 150. In this way, the light emitted from the mercury lamp 66 is on-off controlled by each of the micro-mirrors of the DMD 50, and the substrate 150 is exposed at a unit of pixels (exposure area 168) substantially identical to the number of pixels used in the DMD 50. Further, movement of the substrate 150 at a constant speed with the stage 152 causes the substrate 150 to be sub-scanned by the scanner 162 in the direction opposite to the moving direction of the stage, and a stripe-shaped exposed region 170 is formed by each exposing head 166.

When the sub-scanning of the substrate 150 by the scanner 162 is completed and the rear edge of the substrate 150 is detected by the detection sensors 164, the stage 152 is returned to the original position on the uppermost stream of the gate 160 along the guides 158 by a not shown drive unit. Thereafter, it is moved again along the guides 158 from the upper stream to down stream of the gate 160 at a constant speed.

When the exposure is completed, the substrate 150 with the wiring pattern exposed thereon is developed in the development unit 4, thereby the portion of the resist layer not exposed the wiring pattern is removed, and a resist pattern is formed on the substrate 150. Thereafter, in the etching unit 5, the copper foil, on the substrate 150, on which the resist pattern is formed is etched, and the wiring pattern is formed. Further, in the peel-off unit 6, the resist layer remaining on the substrate 150 is removed.

Next, in the solder resist application unit 7, a solder resist is applied to the substrate on which the wiring pattern is formed, and a solder resist layer is formed. Then, in the exposure apparatus 8, an opening pattern is exposed. Here also, the edge portion of the opening pattern is exposed with greater irradiation energy than in the other region. The substrate on which the opening pattern is exposed is developed in the development unit 9, thereby the portion of the solder resist layer not exposed the opening pattern is removed, and a solder resist pattern is formed. Thereafter, the solder resist layer is solidified in the curing unit 10, and further a nickel-gold plated layer is formed in the plating unit 11, which completes the printed wiring board.

In this way, in the exposure apparatus according to the present embodiment, the wiring pattern and opening pattern are exposed by controlling the irradiation energy such that the irradiation energy of the light beam in the edge portions A4, A5, and A6 of the wiring pattern and opening pattern becomes greater than the irradiation energy of the light beam in the other portion A3′. Thus, the adhesion between the resist layer or the solder resist layer and the substrate may by improved in the edge portions A4, A5, and A6, which may prevent the separation of edge portions of the resist layer and solder resist layer in the subsequent processes after exposure.

For the resist layer, in particular, the developing solution is prevented from intruding between the resist layer and the substrate 150 in the development process after exposure, which allows desired etching and plating to be performed in the subsequent etching and plating processes. Further, greater irradiation energy is applied only to the edge portions of the wiring pattern, so that the resist layer may be removed completely after etching.

For the solder resist layer, the pretreatment solution and plating solution are prevented from intruding between the solder resist layer and the substrate 150 in the plating process after development, and desired plating may be performed satisfactorily. Further, greater irradiation energy is applied only to the edge portion of the opening pattern, so that the photopolymerization reaction does not become excessive, and the solidification contraction falls within a permissible range, which eliminates the likelihood that the solder resist layer is peeled off.

In the present embodiment described above, the wiring pattern and the opening pattern are exposed through a single exposure, using pattern data in which the distance between the light irradiation positions in the edge portions of the wiring pattern and the opening patter is doubled to that for the other portion, the wiring pattern and the opening pattern may be formed through a plurality of exposures. Hereinafter, description will be made of a case in which exposure is performed a plurality of times. The description will be made of a case in which the pattern illustrated in FIG. 9 is exposed, as in the embodiment described above.

First, the entire portion of the region A3 is exposed once with the same irradiation energy. Here, the distance between the light beam irradiation positions is the same across the region A3. The substrate 150 exposed once is returned to the original position, and a second exposure is performed. In the second exposure, the light beam is irradiated only on the pixel positions corresponding to the edge portions A4, A5, and A6. By irradiating the light beam a plurality of times in the manner as described above, the wiring pattern and opening pattern may be exposed with greater irradiation energy in the edge portions A4, A5, and A6 of the wiring pattern and opening pattern than in the other portion A3′.

Note that in the case where a pattern is formed through a plurality of exposures in the manner as described above, the second exposure may be performed by controlling the irradiation energy so as to become greater in the edge portions A4, A5, and A6 of the wiring pattern and opening pattern than in the other portion A3′, as in the embodiment described above.

Further, in the embodiment described above, a pattern exposure is performed using a light beam modulated by pattern data. But the exposure may also be performed by bringing mask films, having openings identical in shape to the wiring pattern and opening pattern respectively, into close contact with the substrate 150 on which the resist layer and solder resist layer are formed respectively. The exposure using such mask film may be a whole surface exposure in which the entire surface is scanned by a light beam, identical to that used in the embodiment described above, having a constant irradiation energy.

FIG. 12 illustrate an example mask film. As illustrated, the mask film M1 is for exposing the same pattern as that illustrated in FIG. 9, and includes a circular region and a square region A 11, A12 within a horizontally long rectangular region A10, a region A13, which is a region other than the regions A11, A12 within the region A10, an edge portion A14 of the circular region A11 within the region A10, an edge portion A15 of the square region A12 within the region A10, an edge portion A16 of the region A13, and a region A17 outside of the region A10.

The optical transmittance of the regions A11, A12, and A17 is zero (blocking light), and the edge portions A14, A15, and A16 within the region A13 have a greater optical transmittance than that of the portion other than the edge portions A14, A15, and A16 within the region A13 (A13′). For example, the optical transmittance of the edge portions A14, A15, and A16 is 100% (total transmission), while the optical transmittance of the other portion A13′ is 50%. This causes the edge portions A14, A15, and A16 to be exposed with the irradiation energy twice as great as the irradiation energy in the other portion A13′.

Note that the irradiation energy of the light beam may be changed variously by changing the optical transmittance. In the present embodiment, it is preferable that the optical transmittance is changed such that the edge portions A14, A15, and A16 are exposed with irradiation energy which is 1.1 to 3.0 times the irradiation energy in the portion A13′.

By performing exposures by brining such mask film M1 into close contact with the substrate 150 on which the resist layer and solder resist layer are formed respectively, the wiring pattern and opening pattern may also be exposed with greater irradiation energy in the edge portions A14, A15, and A16 of the wiring pattern and opening pattern than in the other portion A13′.

Although it is possible to expose the pattern through a single exposure using the mask film illustrated in FIG. 12, the wiring pattern and the opening pattern may be exposed through a plurality of exposures using a plurality of types of mask films. Hereinafter, mask films used in a plurality of exposures will be described.

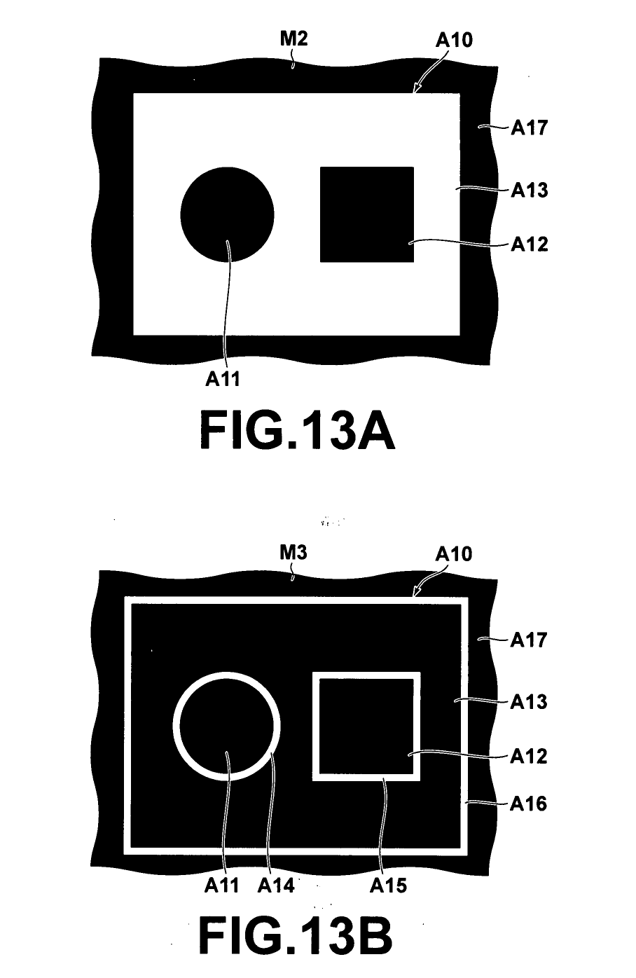

FIGS. 13A and 13B illustrate example mask films used in a plurality of exposures. Description of example mask films will be provided here in which a pattern is formed through two times of exposures. First, a first exposure is performed using a mask film M2 illustrated in FIG. 13A.

The mask film M2 illustrated in FIG. 13A is for exposing the same pattern as that illustrated in FIG. 9, and includes: a circular region and a square region A 11, A12 within a horizontally long rectangular region A10; a region A13, which is a region other than the regions A11, A12 within the region A10; and a region A17 outside of the region A10. The optical transmittance of the regions A11, A12, and A17 is zero (blocking light), and the optical transmittance of the region A13 is 100% (total transmission).

Then, a second exposure is performed using a mask film M3 illustrated in FIG. 13B. The mask film M3 illustrated in FIG. 13B has regions of A10 to A17 similar to those of the mask film M1 illustrated in FIG. 12. But, the optical transmittance of the region A13′ is zero (blocking light), in addition to the regions A11, A12, and A17, and the optical transmittance of the edge portions A14, A15, and A16 is 100% (total transmission).

When performing two exposures in the manner as described above, the wiring pattern and the opening pattern may be exposed, in the second exposure, with greater irradiation energy in the edge portions A14, A15, and A16 of the wiring pattern and opening pattern than in the other portion A13′ using the mask film M1 illustrated in FIG. 12. Performance of two exposures by brining the two mask films M2, M3 into close contact with the substrate 150 on which the resist layer and solder resist layer are formed respectively, the wiring pattern and opening pattern may also be exposed with greater irradiation energy in the edge portions A14, A15, and A16 of the wiring pattern and opening pattern than in the other portion A13′.

In the embodiment described above, a mercury lamp is used as the light source of the exposure apparatus 3, but a laser source may also be used.

Further, in the embodiment described above, the exposure method and apparatus for performing exposure on a printed wiring board have been described, but the present invention is not limited to this. It will be appreciated that the exposure method and apparatus of the present invention may be applied to the exposures of materials of a display, including color filters, pillar materials, lib materials, spacers, partitions, and the like, or to the exposures of recording media for patterning, including holograms, micromachines, proofs, and the like.

Still further, the present invention is not limited to the embodiments described above, and various changes and modifications may be made without departing from the spirit of the invention, such as an exposure apparatus using a laser source, an AOM and a polygon mirror for modulating the leaser source as the optical scanning optical system as described, for example, in Japanese Unexamined Patent Publication No. 2000-227661.

1-12. (canceled)

13. An exposure method for exposing a predetermined pattern on a photosensitive layer, which is stacked on a recording medium and has sensitivity to light emitted from a predetermined light source, with the light having predetermined irradiation energy,
wherein the predetermined pattern is exposed on the photosensitive layer with greater irradiation energy in an edge portion of the predetermined pattern than in the other portion thereof.

14. The exposure method according to claim 13, wherein:
the predetermined light source is a light source that emits a light beam; and
the predetermined pattern is exposed on the photosensitive layer by scanning the recording medium with the light beam, while controlling the irradiation energy of the light beam so as to become OFF in a region of the recording medium other than the predetermined pattern, and to become greater in the edge portion of the predetermined pattern than in the other portion thereof.

15. The exposure method according to claim 13, wherein:
the predetermined light source is a light source that emits a light beam; and
the predetermined pattern is exposed on the photosensitive layer by scanning the recording medium with the light beam such that the light beam becomes OFF in a region of the recording medium other than the predetermined pattern and becomes ON in the region of the predetermined pattern, and, after the scanning, scanning the recording medium with the light beam such that the light beam becomes ON only in the edge portion of the predetermined pattern.

16. The exposure method according to claim 13, wherein:
the predetermined light source is a light source that emits a light beam; and
the predetermined pattern is exposed on the photosensitive layer by scanning the recording medium with the light beam such that the light beam becomes OFF in a region of the recording medium other than the predetermined pattern and becomes ON in the region of the predetermined pattern, and, after the scanning, scanning the recording medium with the light beam, while controlling the irradiation energy of the light beam so as to become OFF in the region of the recording medium other than the predetermined pattern, and to become greater in the edge portion of the predetermined pattern than in the other portion thereof.

17. The exposure method according to claim 13, wherein the predetermined pattern is exposed on the photosensitive layer by irradiating the light on the recording medium through a mask film which optically masks a region of the recording medium other than the predetermined pattern and has a greater transmittance in the region thereof corresponding to the edge portion of the predetermined pattern than in the region thereof corresponding to the other portion of the predetermined pattern.

18. The exposure method according to claim 13, wherein the predetermined pattern is exposed on the photosensitive layer by irradiating the light on the recording medium through a first mask film, which optically masks a region of the recording medium other than the predetermined pattern and transmits light in the region thereof corresponding to the predetermined pattern, and through a second mask film, which transmits light only in the region thereof corresponding to the edge portion of the predetermined pattern, or has a greater transmittance in the region thereof corresponding to the edge portion of the predetermined pattern than in the region thereof corresponding to the other portion of the predetermined pattern, respectively.

19. An exposure apparatus for exposing a predetermined pattern on a photosensitive layer, which is stacked on a recording medium and has sensitivity to light emitted from a predetermined light source, with the light having predetermined irradiation energy,
wherein the apparatus comprises an exposure control means for exposing the predetermined pattern on the photosensitive layer with greater irradiation energy in an edge portion of the predetermined pattern than in the other portion thereof.

20. The exposure apparatus according to claim 19, wherein:
the predetermined light source is a light source that emits a light beam; and
the apparatus further comprises a scanning means for modulating and scanning the light beam according to the predetermined pattern; and
the exposure control means is a means for controlling the scanning means such that the predetermined pattern is exposed on the photosensitive layer by scanning the recording medium with the light beam, while controlling the irradiation energy of the light beam so as to become OFF in a region of the recording medium other than the predetermined pattern, and to become greater in the edge portion of the predetermined pattern than in the other portion thereof.

21. The exposure apparatus according to claim 19, wherein:
the predetermined light source is a light source that emits a light beam;
the apparatus further comprises a scanning means for modulating and scanning the light beam according to the predetermined pattern; and
the exposure control means is a means for controlling the scanning means such that the predetermined pattern is exposed on the photosensitive layer by scanning the recording medium with the light beam such that the light beam becomes OFF in a region of the recording medium other than the predetermined pattern, and becomes ON in the region of the predetermined pattern, and, after the scanning, scanning the recording medium with the light beam such that the light beam becomes ON only in the edge portion of the predetermined pattern.

22. The exposure apparatus according to claim 19, wherein:
the predetermined light source is a light source that emits a light beam; and
the exposure control means is a means for controlling the scanning means such that the predetermined pattern is exposed on the photosensitive layer by scanning the recording medium with the light beam such that the light beam becomes OFF in a region of the recording medium other than the predetermined pattern, and becomes ON in the region of the predetermined pattern, and, after the scanning, scanning the recording medium with the light beam, while controlling the irradiation energy of the light beam so as to become OFF in the region of the recording medium other than the predetermined pattern, and to become greater in the edge portion of the predetermined pattern than in the other portion thereof.

23. The exposure apparatus according to claim 19, wherein the exposure control means is a means for exposing the predetermined pattern on the photosensitive layer by irradiating the light on the recording medium through a mask film, which optically masks a region of the recording medium other than the predetermined pattern and has a greater transmittance in the region thereof corresponding to the edge portion of the predetermined pattern than in the region thereof corresponding to the other portion of the predetermined pattern.

24. The exposure apparatus according to claim 19, wherein the exposure control means is a means for exposing the predetermined pattern on the photosensitive layer by irradiating the light on the recording medium through a first mask film, which optically masks a region of the recording medium other than the predetermined pattern and transmits light in the region thereof corresponding to the predetermined pattern, and through a second mask film, which transmits light only in the region thereof corresponding to the edge portion of the predetermined pattern, or has a greater transmittance in the region thereof corresponding to the edge portion of the predetermined pattern than in the region thereof corresponding to the other portion of the predetermined pattern, respectively.
